(19) United States
(12) Patent Application Publication
(10) Pub. No.: US 2001/0047758 A1
(43) Pub. Date: Dec. 6, 2001

(54) APPARATUS AND METHOD FOR COATING A SUBSTRATE BY MEANS OF A CHEMICAL GAS PHASE CORPORATION PROCESS

(76) Inventors: THORSTEN MATTHEE, MEINE (DE); ROLF SIX, HENSTEDT-ULZBURG (DE); ALEXANDER HAMPEL, BRAUNSCHWEIG (DE)

Correspondence Address: SALTER & MICHAELSON, 321 SOUTH MAIN STREET, PROVIDENCE, RI, 02903

(21) Appl. No.: 09/009,394

(22) Filed: Jan. 20, 1998

(30) Foreign Application Priority Data
Jan. 20, 1997 (DE) 197 01 696.0

(51) Int. Cl. C23C 16/00

(52) U.S. Cl. 118/718; 118/724

(57) ABSTRACT

In an apparatus for coating a substrate by means of a chemical gas phase separation process, the arrangement of the filaments (5, 17, 26) at least partially surrounding the substrate to be coated is not merely two-dimensional but three-dimensional in respect of the substrate.

The invention relates to an apparatus and a method for coating a substrate by means of a chemical gas phase separation process.

Diamond-faced tools in particular, e.g. for machining, are coated by this known process. A diamond coating must adhere to the tool; it is normally polycrystalline. An activated gas phase is used in the process, and the substrate generally has a temperature of 700 to 950° C. during coating.

The filaments are wires which are clamped parallel with each other in one plane. This flat arrangement of the filaments may be horizontal or vertical.

There is an example of the flat arrangement of wave-form filaments in EP 0 545 542 A1. The filament or filaments are formed in wave-form in one plane above a substrate to be coated. The substrate table is also flat, and the filament arrangement is provided parallel with it.

Experience shows that non-homogeneous temperature distributions, which then lead to non-homogeneous coatings, are generally obtained in this process, particularly with substrates of complex shape but even with round tools such as grinding wheels.

The problem of the invention is to obtain more homogeneous coating of substrates by means of a chemical gas phase separation process.

The problem is solved by a not merely two-dimensional arrangement of the filaments at least partially surrounding the substrate to be coated, but a three-dimensional arrangement in respect of the substrate. Other features of the invention are defined in the sub-claims.

Uniform coating of substrates of complex shapes firstly requires uniform activation of the gas phase through uniform spacings between the filaments themselves and between the filaments and the substrate. Secondly it requires uniform temperature distribution on the whole surface of the substrate to be coated. Adaptation of the filaments to the substrates becomes necessary approximately from a diameter of d=10 mm in the case of cylindrical substrates.

With an apparatus according to the invention and thus a departure from the previous, always flat filament geometry, it now becomes possible to ensure a homogeneous enough coating thickness when coating tools and components of a complex shape. Shadowing effects such as appear chiefly with flat filament arrangements are substantially avoided by having the substrates completely enclosed by filaments. The necessary current intensity can be reduced by using the two half-shells and the short-circuiting ring. Consequently the electric power which is lost as heat in the supply lines is less than in known methods of coating with a flat arrangement of filaments.

When the alternative embodiment without a short-circuiting ring is used, the arrangement is given great flexibility through the length of the filaments. Tools of the most varied diameters can be coated, or a plurality of tools simultaneously.

The problem is also solved by a method of coating a substrate by a chemical gas phase separation process characterised by simultaneous coating of the substrate from more then one side. The shape in which the filaments are suspended advantageously corresponds to the shape of the tool to be coated. A round filament retainer is preferably provided for round tools. Such an embodiment of the apparatus has two half-shells and a short-circuiting ring. The filaments are clamped between the two half-shells, which are connected to the power supply, and the short-circuiting ring. They advantageously run in a straight line between the two half-shells and the ring. The tool to be coated is inserted in the apparatus vertically. The fact that the tool to be coated is completely surrounded by the coating apparatus means that it is coated from all sides simultaneously. An advantageous alternative embodiment has no short-circuiting ring at the bottom. The filaments are clamped in two holders of straight or curved shape. They hang down unclamped, by gravity, forming a curve at the bottom. In this embodiment the tool to be coated is installed with its axis of rotation horizontal. It is rotated uniformly during the coating process. The tool is indeed coated evenly in the region of the curved filaments, but if it were not rotated the coating in the upper part, not surrounded by the filaments, might be non-homogeneous. A radiation screen for example is advantageously arranged in that part, so that little heat can rise and be lost from the apparatus. Preferably the chemical gas phase separation process is a chemical vapour deposition process (CVD-process).

The invention will now be explained in greater detail, by describing embodiments of an apparatus for coating a substrate by a chemical gas phase separation process, with reference to the accompanying drawings in which:

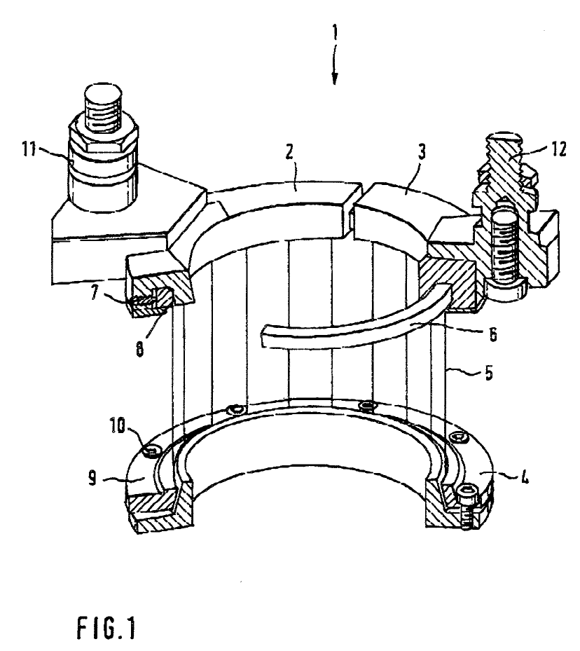

FIG. 1 is a perspective view of a first embodiment of a coating apparatus according to the invention;

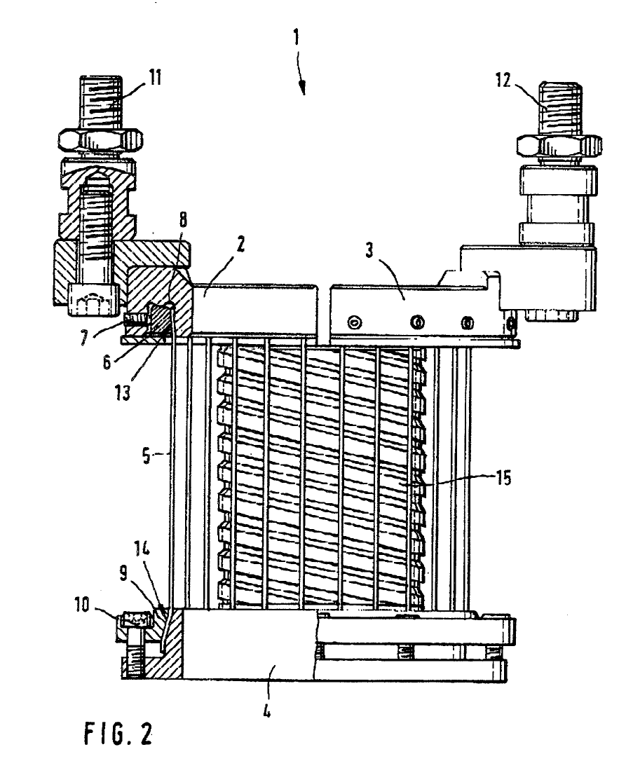

FIG. 2 is a part-sectional side view of the FIG. 1 apparatus;

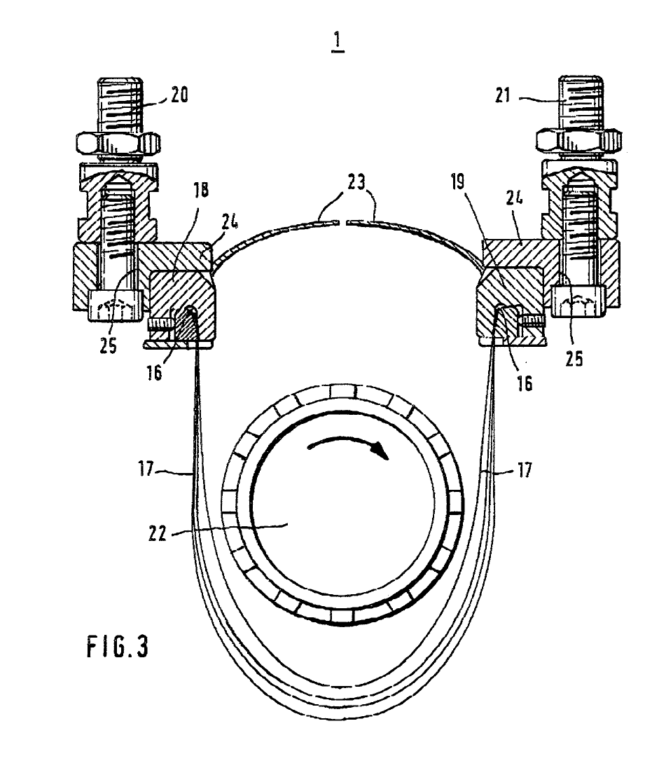

FIG. 3 is a part-sectional side view of a second embodiment of a coating apparatus according to the invention; and

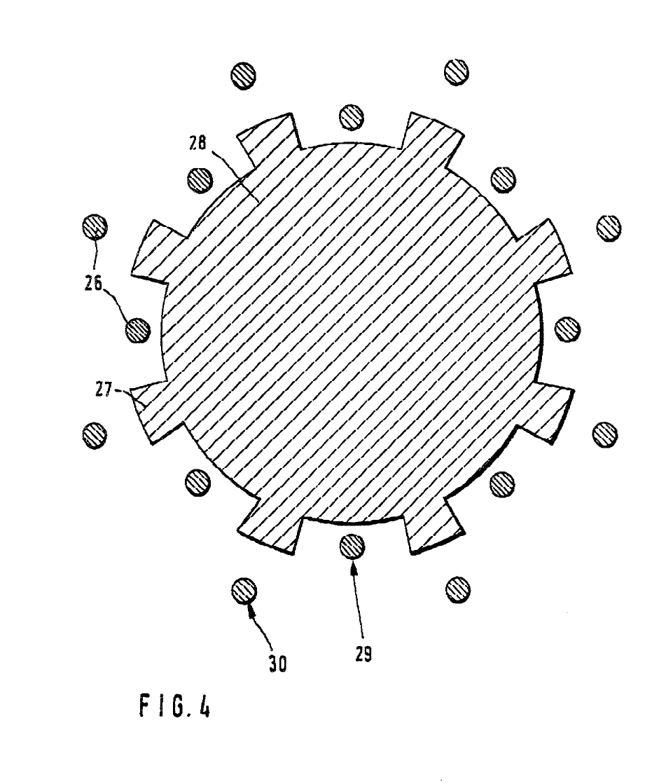

FIG. 4 is a sectional view or a third embodiment of an apparatus according to the invention.

FIG. 1 gives a perspective view of a first embodiment of an apparatus 1 for coating a substrate (not shown). The upper part of the apparatus 1 has two half-shells 2, 3. The lower part has a short-circuiting ring. Filaments 5 are clamped in between the two half-shells 2, 3 and the ring. The filaments 5 extend in straight lines between the two half-shells and the short-circuiting ring. A segmented filament retaining ring 6 is shown projecting from one half-shell 3. The filaments 5 are fixed in filament retainers 8 in the two half-shells 2, 3 by the filament retaining ring 6 in combination with screws 7 at the outer periphery of the two half-shells.

The filaments 5 are fixed in the short-circuiting ring 4 by means of a clamping ring 9. This works together with screws 10.

The two half-shells 2, 3 are connected to power supply leads 11, 12. By using the two half-shells the necessary intensity of the current supplied by the two leads 11, 12 to the two half-shells 2, 3 and thus to the filaments 5 is reduced to below 1000 Å. It is necessary though for the filaments to be held in the filament retainer 8 and short-circuiting ring 4 so that electrical contact is equally good for all filaments, i.e. is of low impedance. Differential heating of individual filaments is avoided in this way. This can be seen more clearly from FIG. 2.

FIG. 2 is a part-sectional side view of the FIG. 1 apparatus. As a means of ensuring uniform electrical contacting of the filaments these must undergo uniform plastic deformation. On the one hand the filaments 5 have to be clamped in straight. This is shown in FIG. 2. In order to obtain low-impedance contacting of the filaments in the retainer 8 and short-circuiting ring 4, the filament retaining ring 6 and clamping ring 9 are made tapering, with a respective bevelled wall 13, 14. The two retaining rings 6 inside the two half-shells 2, 3 are severed obliquely, in order not to worsen contact-making at the abuting surfaces of the two rings.

By providing a smooth surface inside the filament retainers in the two half-shells 2, 3 and the short-circuiting ring 4 different, freely chosen spacings can be obtained between the filaments 5. In this way different numbers of filaments can be accommodated inside the apparatus 1. This gives greater variety in respect of the tools 15 to be coated. The tools are arranged vertically in the apparatus as indicated. The filaments should everywhere be at a uniform spacing of approximately 10 mm from the tool surface to be coated. Uniform and optimum coating of the tool thus becomes possible. Through being encased on all sides by the filaments in the apparatus, the tool surface or substrate is coated evenly and homogenously, since there is homogeneous temperature distribution throughout the apparatus.

Filament grids may be clamped in instead of the individual filaments 5. Retention of such grids in the short-circuiting ring and two half-shells is easier than when a plurality of individual filaments are provided. Installation of one or more grids also gives still more homogenous temperature distribution in the apparatus 1. Filament temperature of above 1900° C. to a maximum of 2700° C. are reached in the apparatus according to the invention. The filament retaining ring, short-circuiting ring and clamping ring are made of molybdenum or another high melting point metal, so that they are not melted by contact with the hot filaments.

Different filament diameters may be used, for example d—0.5 mm to 1.5 mm, as the filament retaining ring is segmented and the segments are tapered. As the short-circuiting ring 4 and clamping ring 9 have tapered clamping surfaces different filament diameters can be clamped in.

With small filament diameters the screws 10 are no longer required, provided that the tapering clamping surfaces are designed with sufficient clamping strength to clamp in the filaments without screws. This reduces the weight, eliminating the screws themselves and the material required to insert the screw thread in the short-circuiting ring 4 and clamping ring 9.

FIG. 3 is a part-sectional view of a second embodiment of a coating apparatus 1 according to the invention. Unlike the apparatus shown in FIG. 1 and FIG. 2 the FIG. 3 apparatus has no short-circuiting ring 4. The filaments 17 clamped into a retainer 16 hang down from it by gravity with a slight curvature. They approximately match a cylindrical substrate. The two filament retainers 16 form part of the two holders 18, 19. The two holders are provided parallel with and of a predetermined spacing from each other. The shape of the two holders 18, 19 is preferably not rounded but straight. However they may also have curves to adapt them to a correspondingly shaped tool.

The two holders 18, 19 are provided with power supply leads 20, 21. The tool 22 to be coated is inserted in the apparatus 1 with horizontal orientation. The filaments 17 hanging down encase the tool. Heat discharged by the filaments in the coating process could only be wasted at the top where no filaments 17 are provided. In order to prevent this a radiation screen 23 is provided on each of the two holders 18, 19. The tool is turned about its horizontal axis of rotation within the apparatus 1 to ensure homogeneous coating.

The advantage of this apparatus over that in FIG. 1 is that the space between the two holders 18, 19 allows tools of different diameter to be held in the apparatus, since adaptation to the appropriate diameters can take place. Such adaptation to different tool diameters is also obtained through the different filament lengths which can be selected. The filaments may be adapted to different substrate diameters by means of a slot 25 provided in a holder 24, by displacing the holder 24. The length of the filaments is adapted to the substrate to be coated. The flexibility of the apparatus is therefore obtained through the length of the filaments. In this embodiment a plurality of tools can furthermore be inserted in the apparatus simultaneously and coated therein.

A third embodiment of apparatus 1 according to the invention is shown in section in FIG. 4. The structure of the apparatus 1 is almost identical with that in FIGS. 1 and 2. The only difference is that two rows of filaments 26 are provided in the FIG. 4 embodiment instead of just one row. A tool or substrate 28 is inserted vertically in the apparatus. Hence the filaments 26 are shown in section. The tool 20 has projections 27. The inner row 29 of filaments 26 is arranged with a filament between each pair of projections 27 from the tool 28. The outer row 30 of filaments 26 on the other hand is arranged with a filament in front of each such projection 27. Each of the filaments 26 in the two rows is therefore in a gap between filaments. Through the provision of these filaments 26, arranged concentrically and offset from each other, the gaps between the projections 27 form the tool 28 are coated to the optimum. The apparatus illustrated, with the filaments 26 in two rows, has proved to be particularly advantageous, specifically for tools of the type shown in FIG. 4.

### LIST OF REFERENCES

01 apparatus

02 half-shell

03 half-shell

04 short-circuiting ring

05 filaments

06 filament retaining ring

07 screws

08 filament retainer

09 clamping ring

10 screws

11 power supply lead

12 power supply lead

13 tapered wall

14 tapered wall

15 tool

10 filament retainer

17 filaments

18 holder

19 holder

20 power supply lead

21 power supply lead

22 tool

23 radiation screen

24 holder

25 slot

26 filaments

27 projection

28 tool

29 inner row

30 outer row

1. Apparatus for coating a substrate by means of a chemical gas phase separation process, characterised by a not merely two-dimensional arrangement of the filaments (5, 17, 26) at least partially surrounding the substrate to be coated, but a three-dimensional arrangement in respect of the substrate.

2. Apparatus according to claim 1, characterised in that the filaments (5, 17, 28) completely surround the substrate to be coated.

3. Apparatus according to claim 2, characterised in that the suspension of the filaments matches the shape of the substrate to be coated or of a tool (15, 22).

4. Apparatus according to claim 3, characterised in that the filaments are at a spacing of 1 mm to 30 mm from the substrate surface to be coated.

5. Apparatus according to claim 1, characterised in that the filaments (5) are clamped in a straight line between two near semi-circular half-shells (2, 3) and a short-circuiting ring arranged parallel therewith.

6. Apparatus according to claims 1, characterised in that the filaments (17) are clamped at both ends in holders (18, 19) arranged parallel with each other, and that a curvature is formed by the dead weight of the filaments (17).

7. Apparatus according to claim 6, characterised in that radiation screens (23) are arranged on the holders (18, 19) as a protection from heat loss.

8. Apparatus according to claim 6, characterised in that holders (24) have slots (25) for flexibly clamping in filaments (17) of different lengths.
